(19) United States
(12) Patent Application Publication
(10) Pub. No.: US 2006/0157702 A1
(43) Pub. Date: Jul. 20, 2006

(54) Kerf with improved fill routine

(75) Inventors: Sibina Sukman-Prahofer, Munchen (DE); Susanne Lachenmann, Munchen (DE); Valentin Rosskopf, Pottmes (DE); Ramona Winter, Munchen (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munchen (DE)

(21) Appl. No.: 11/334,754

(22) Filed: Jan. 19, 2006

(30) Foreign Application Priority Data
Jan. 20, 2005 (DE) 10 2005 002 678.8

(51) Int. Cl. H01L 23/58; H01L 21/66

(52) U.S. Cl. 257/48; 438/18

(57) ABSTRACT

A semiconductor disk which exhibits chip areas arranged next to one another and separated from one another by a kerf. The chip areas in each case exhibit a multiplicity of similar device patterns, such that at least one fill area with fill patterns is arranged in the kerf, and the fill patterns in the kerf and the device patterns in the chip areas are essentially similarly constructed.

### CLAIM FOR PRIORITY

This application claims the benefit of priority to German Application No. 10 2005 002 678.8, filed in the German language on Jan. 20, 2005, the contents of which are hereby incorporated by reference.

### TECHNICAL FIELD OF THE INVENTION

The invention relates to an arrangement of fill patterns in the kerf of a semiconductor wafer, and to a method for producing such cell-array-like fill patterns in the kerf.

### BACKGROUND OF THE INVENTION

During the production of integrated circuits, microelectronic patterns are produced on thin semiconductor disks, so-called wafers. During this process, a number of integrated circuits are simultaneously generated lithographically as separate chips on a wafer and are processed arranged next to one another on the wafer. Between the individual chips of a wafer, a so-called kerf (scribe frame) is provided which separates the chips from one another. In this kerf, test patterns and associated test pads are arranged. These test patterns form monitoring and reliability patterns which are used for performing predetermined measuring and test steps. Using these measuring and test steps, information about the current production process and the functional capabilities and reliability of the actual useful patterns on the chip can be derived. As a rule, the test pads in the kerf are used as contacts for test probes of a special automatic tester. At the end of the production process, the kerf is finally used as sawing edge, along which the wafer is sawn into individual chips.

To create optimum production conditions for the microelectronic patterns, certain process and design rules must be met. In this context, adherence to particular density rules is very important especially for lithography, etching or CMP (chemical-mechanical polishing). Thus, negative effects can occur, e.g. during the polishing of inhomogeneous arrangements of semiconductor patterns, which lead to unwanted erosion in the edge areas of these arrangements. Furthermore, an inhomogeneous distribution of the semiconductor patterns on a wafer can lead to unwanted charging in certain areas during the etching which leads to a changed etching behavior in these areas. This can result in nonuniform erosion of the semiconductor patterns along the wafer.

To achieve the packing densities necessary for these processes, fill routines are normally used which automatically generate fill areas (also called fill) with fill patterns in the kerf. For this purpose, fill areas which are filled with reticular polysilicon or rectangular diffusion structures, respectively, are automatically generated in free areas of the kerf. Due to the relaxed design rules for line widths and distances, the fill patterns generated during this process have much greater dimensions than the cell array.

Since it is not only the packing density over a certain window size (e.g. 100×100 μm²) but also the fine patterns which are of importance for optimum lithographic conditions, this automatic fill with the corresponding design rules has not hitherto been found to be adequate for the entire production process but rather only for the process technique (polishing, CMP). Since the semiconductor patterns created are becoming smaller and smaller, it is necessary to build in supporting patterns for the lithography. In addition, an improved fill routine will also soon become necessary for the process technique as the integration density progresses.

### SUMMARY OF THE INVENTION

The invention relates to an arrangement of fill patterns in the kerf of a semiconductor wafer. The fill structures are preferably constructed in the manner of a cell array and arranged underneath contact patterns arranged in the kerf. The invention also relates to a method for producing such cell-array-like fill patterns in the kerf.

The invention seeks to improve the production conditions for integrated circuits.

According to one embodiment of the invention, a semiconductor disk is proposed which exhibits a number of chip areas arranged next to one another, which are separated from one another by a kerf. The chip areas in each case exhibit a multiplicity of similar device patterns. At least one fill area in the kerf which exhibits fill patterns is provided. According to the invention, the fill patterns in the kerf and the device patterns in the chip areas are essentially similarly constructed. An essential advantage of this construction includes, as a result, the packing density of the device-pattern-like elements can be improved on the entire wafer surface. An improved packing density of such patterns leads to optimized design rules for lithography, etching and CMP. The production conditions for integrated circuits can thus be improved.

Since the new fill pattern is preferably drawn in the manner of a cell array, the exposure settings during the process are adapted to the cell array. This guarantees optimum imaging. A higher packing density is thus achieved. A cell-array-like pattern in the kerf considerably improves the rendition of the patterns outside the cell array which also improves the rendition of the test patterns.

An advantageous embodiment of the semiconductor disk exhibits fill patterns in the fill area which exhibit the same line widths and distances as the device patterns in the chip areas. As a result, in particular, the conditions can be optimized for lithography.

A particularly advantageous embodiment of the invention includes providing in the fill area fill patterns having the same topography as the device patterns in the chip areas. The result is that, in addition to the same packing density, the fine patterns of the device and of the fill patterns also match. This is of particular importance for the lithography. Furthermore, it reduces the volume of data for the fill routine since now cell-array-like patterns are used instead of the complex fill patterns usually generated separately.

A further advantageous embodiment of the invention provides for the fill areas to be arranged underneath a contact pattern which is formed in the area of the kerf. The fill pattern is electrically insulated from the contact pattern arranged above it by means of a dielectric layer. As a result, the packing density of the cell-array-like patterns can be improved in a particularly advantageous manner. The distribution of these patterns over the entire wafer thus becomes more homogeneous. Since the fill areas are arranged underneath the contact patterns, the placement effort is reduced. This fill is insulated from the metal layers of the contact pattern as a result of which the measurability of the contact patterns is not influenced.

In a further advantageous embodiment of the invention, it is provided that each chip area comprises at least one cell array with a multiplicity of memory cells, the device patterns being constructed as polysilicon and/or diffusion patterns of the cell arrays. Memory cell arrays, in particular, exhibit a high density of similar semiconductor patterns. This leads to problems in the lithography, where unwanted effects occur in the edging areas of the cell arrays. The present invention is, therefore, particularly suitable for producing memory chips.

In a further advantageous embodiment of the invention, it is provided that the similarly constructed patterns in the cell array and in the kerf are essentially homogeneously distributed over the entire semiconductor disk. As a result, optimum production conditions can be achieved particularly for lithography.

### BRIEF DESCRIPTION OF THE DRAWINGS

In the text which follows, the invention will be presented in greater detail with reference to drawings, in which:

FIG. 1 shows a semiconductor disk with separate chip areas and kerfs.

FIG. 2 shows four chip areas and test pads in the kerf.

FIG. 3 shows a cross section through a conventional contact pattern in the kerf.

FIG. 4 shows a cross section through a contact pattern according to the invention in the kerf.

FIG. 5 shows the layout of a fill cell underneath a contact pattern in the kerf.

FIG. 6 shows the layout of a conventional contact pattern in the kerf.

FIG. 7 shows the layout of a contact pattern according to the invention with fill in the kerf.

FIG. 8 shows a conventional test pattern area in the kerf.

FIG. 9 shows a test pattern area according to the invention.

### DETAILED DESCRIPTION OF THE INVENTION

The semiconductor disks described in the text which follows in each case exhibit a number of memory chips. Such chips, constructed, e.g. as DRAM or flash memory, exhibit a multiplicity of similar patterns, as a rule. The production conditions for these memory chips can thus be improved, in particular, with the aid of the invention. However, the application of the invention is not restricted to memory chips.

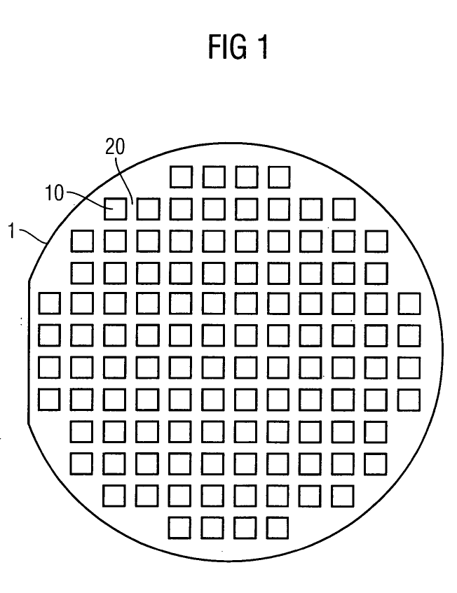

FIG. 1 shows a wafer map by way of example. The wafer (semiconductor disk) 1 shown diagrammatically exhibits a number of semiconductor chips which are arranged as chip areas 10 on the wafer 1. The chip areas 10, uniformly distributed over the wafer surface, are separated from one another by a kerf 2. At the end of the production process, the kerf 20 is used as sawing edge, along which the wafer 1 is sawn apart and split into individual chips.

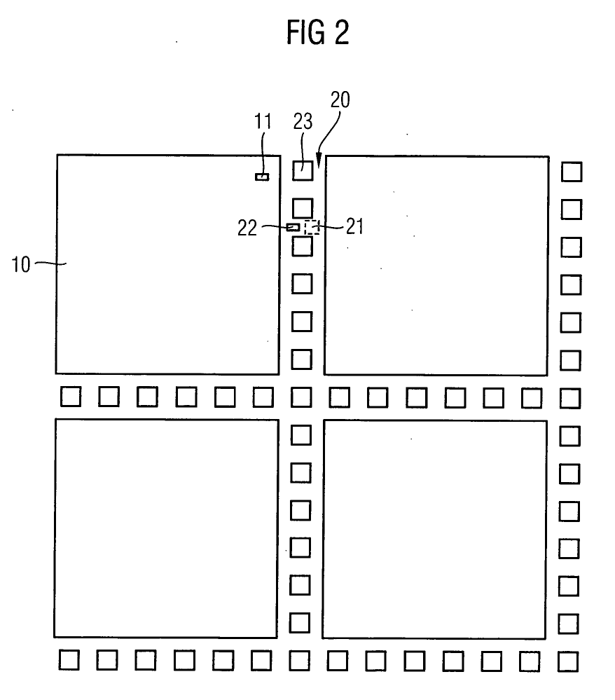

FIG. 2 diagrammatically shows a section of the wafer map from FIG. 1 with four adjacent chip areas 10 and a part of the kerf 20 extending between the chip areas 10. As a rule, a multiplicity of device patterns 11 are arranged in the chip areas 10, only a single device pattern 11 being shown diagrammatically in FIG. 2 for reasons of clarity. In a semiconductor memory such as, e.g. DRAM or flash memory, these patterns 11 are constructed as a rule as polysilicon and diffusion areas GC, AA.

Such microelectronic patterns 11 are created on the surface of the semiconductor disk 1 with the aid of known production methods. In this context, certain process or design rules should be met in order to achieve optimum production conditions. Density rules, that is to say the distribution of patterns over the entire wafer 1, represent important conditions especially for lithography, etching or CMP (chemical-mechanical polishing). If these rules are not taken into consideration, unwanted effects can occur during the production process which negatively influence the functional capability of the end product.

A packing density necessary for these processes has hitherto been achieved by means of automatic fill routines. In these routines, fill areas 21 are automatically generated in the free areas of the kerf 20. The fill areas 21 include fill patterns which are constructed as reticular polysilicon patterns or, respectively, as diffusion patterns in rectangular form. For the fill areas 21 in the kerf 20, relaxed design rules are used for line widths and distances so that the fill patterns generated during this process have much larger dimensions than the device patterns 11 in the chip areas 10. This is found to be critical, particularly for lithography, and leads to rendering problems even with present-day integration density. A cell-array-like fill routine could hitherto not be achieved without relatively great effort due to complicated edge compensations.

As is shown in FIG. 2, metallic contact patterns 23 are arranged in the kerf 20. These contact patterns 23 are here constructed as so-called test pads and connected to test patterns 25 also arranged in the kerf 20. The test pads 23 are used as contacts for a probe card of an external automatic tester which is connected to the test patterns 25 (not shown here). As a rule, the test patterns 25 correspond to patterns in the chip area 10. Measurements on these test patterns 25 provide information about the functional capability of the device patterns 11 created in the chip areas 10. For reasons of clarity, one device pattern and one test pattern 11, 25 is in each case shown diagrammatically in FIG. 2.

The structure of the contact patterns 23 in the kerf can vary depending on application. To ensure reliable contact between the contact patterns 23 and external contact pins, however, the contact patterns 23 must exhibit a relatively large lateral extent. As indicated diagrammatically in FIG. 2, a large proportion of the area in the kerf 20 is, therefore, occupied with contact patterns 23. In contrast, the test patterns 25, frequently constructed analogously to the device patterns 11, only take up a small proportion of the kerf area, as a rule. Accordingly, there is less area of the kerf 20 available for the fill areas 21 conventionally generated in the gaps between the contact patterns 23 and the test patterns 25.

Using the concept according to the invention, it is intended, especially in the case of semiconductor memories to distribute the density of the DRAM or flash cell arrays as uniformly as possible over the reticle. A cell array of such a memory includes diffusion and polysilicon, among other things. In the kerf 20, the test patterns 25 only take a small proportion of the area in such memories, i.e. packing with diffusion and polysilicon areas, particularly the packing with cell array areas, is low. The largest area of the kerf 20 is occupied with test pads 23 to which the test patterns 25 are connected. Due to the multiplicity of test pads 23, which only consist of metal planes M0, M1, M2, the required density for the processing of diffusion and polysilicon can no longer be achieved.

According to the invention, therefore, fill areas 21 which are filled with cell-array-like fill patterns are provided in the kerf of the wafer 1. The fill patterns preferably exhibit the same line widths and distances as the device patterns 11 in the chip areas 10. Furthermore, fill patterns with the same topography as the device patterns 11 are provided. The fill areas 21 in this arrangement can be arranged in the gaps between the test patterns 25 and the contact patterns 23 as normal. To further increase the packing density of semiconductor disk 1 with cell-array-like patterns, however, it is provided to provide the fill areas 21 underneath the contact patterns 23. Furthermore, cell-array-like fill patterns can be used as fill for the remaining reticle.

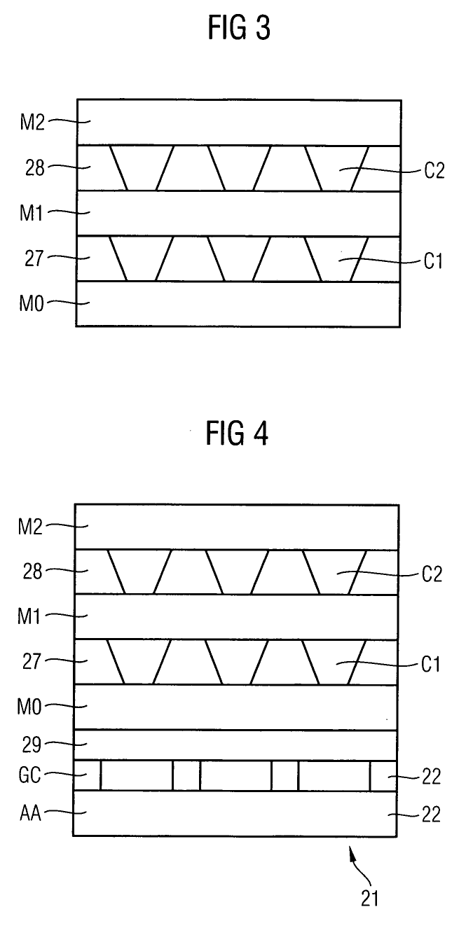

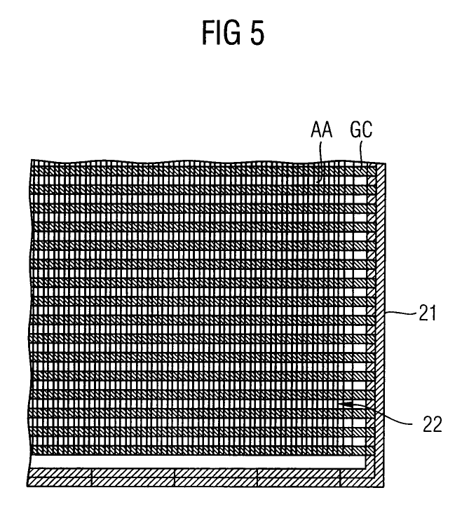

FIGS. 3 and 4 show a comparison between a conventional contact pattern and a contact pattern according to the invention with integrated fill option.

FIG. 3 firstly shows a cross section through a conventional contact pattern 23 in the kerf 20 of the wafer 1. The plane contact pattern 23 essentially includes three metal layers M0, M1, M2 arranged above one another, which are in each case separated from one another by a dielectric layer 27, 28, so-called ILD (inter-level dielectric). Contacts C1, C2, which are constructed, e.g. as aluminum plugs in the dielectric layers 27, 28, are used as connections between the metal layers M0, M1, M2. The lowest metal layer M0 is constructed directly on the semiconductor surface. As a rule, it consists of tungsten. The top metal layer M2 exhibits a relatively large lateral extent and is used directly as contact area for a contact pin of the probe card.

In contrast, FIG. 4 shows a cross section through a contact pattern 23 in the kerf 20 of the wafer 1 according to the invention. The contact pattern 23 according to the invention essentially exhibits the same structure as the conventional metal contact shown in FIG. 3. In this arrangement three metal layers M0, M1, M2 arranged above one another are provided which are in each case separated from one another by a dielectric layer (ILD layer) 27, 28. The metal layers M0, M1, M2 are in each case electrically connected to one another via metal contacts C1, C2 which are constructed in the dielectric layers 27, 28 between the metal layers M0, M1, M2. In contrast to the conventional test pad, the contact pattern 23 according to the invention in the kerf 20 exhibits additional fill patterns 22 underneath the metallization planes M0, M1, M2. According to the invention, these fill patterns 22 exhibit the same structure as the device patterns 11 in the chip areas 10. In this arrangement, in particular, fill patterns 22 are used which exhibit the same topography as the device patterns 11 in the chip areas 10. In the case of a wafer 1 with memory chips, the fill patterns 22 are preferably constructed as cell-array-like polysilicon and diffusion areas AA, GC.

Due to the identical construction of the fill patterns 22 in the kerf 20 and of the device patterns 11 in the chip areas 10, the packing density of the wafer 1 can be increased with cell-array-like patterns for lithography. In this context, the arrangement of the fill patterns 22 underneath contact patterns 23 leads to an even better packing density.

So that the measurability of the contact patterns 23 is not influenced, the fill patterns 22 are not electrically connected to the bottom metal layer M0 in contrast to the device patterns 11. This can be achieved by a dielectric layer 29 between the fill patterns 22 and the lowest metal layer M0, in which no metal plugs are provided.

FIG. 5 shows a section of a fill area 21 according to the invention (fill cell) in the kerf of a semiconductor disk with DRAM or flash memory chips, respectively. The memory chips exhibit cell arrays with a multiplicity of polysilicon and diffusion patterns. These cell array patterns are constructed to be reticular or rectangular, respectively. The strips extending horizontally and vertically exhibit very small line widths and distances. The rectangular fill cell 21 shown in FIG. 5 exhibits fill patterns 22 which are constructed analogously to the cell array patterns. In this arrangement, the fill patterns 22, also constructed as polysilicon and diffusion patterns, preferably exhibit the same line widths and distances as the cell array structures. Such fill cells 21 are preferably arranged underneath test pads.

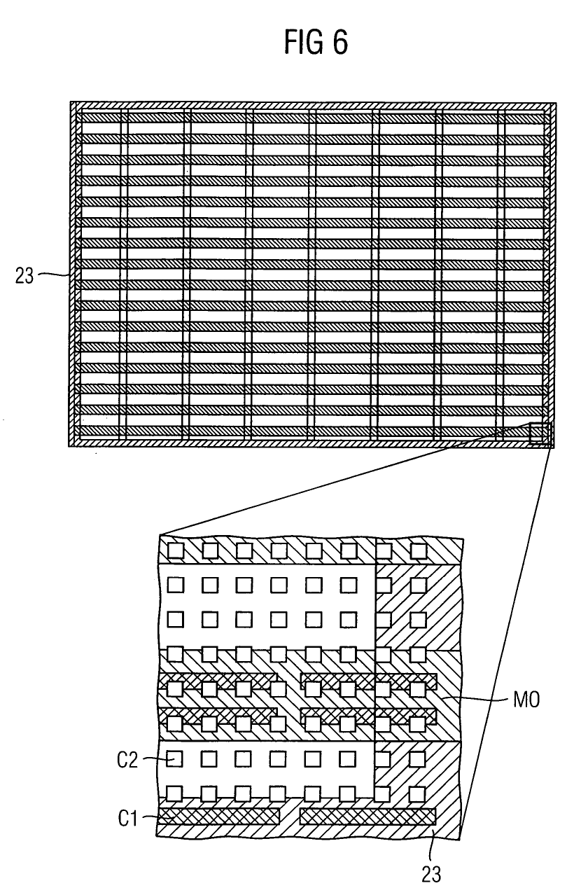

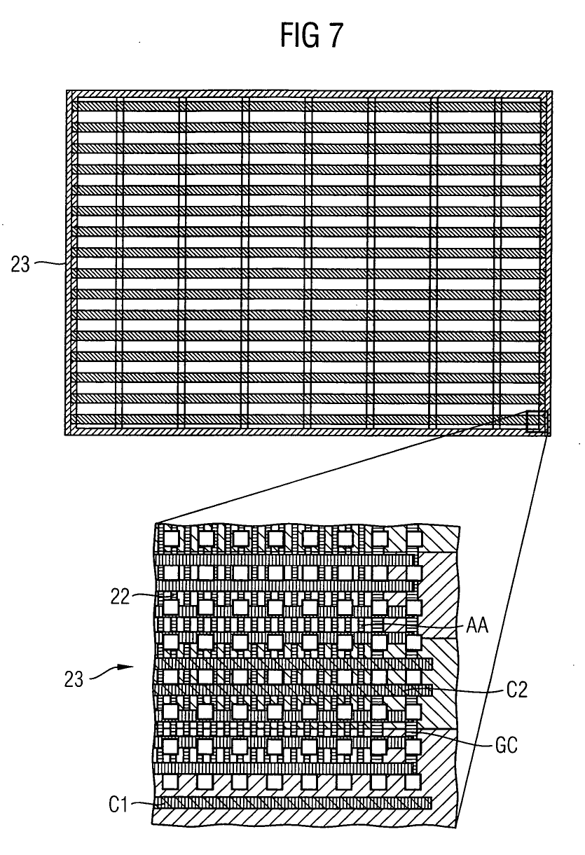

By comparison, FIGS. 6 and 7 show the structure of a conventional contact pattern 23 and of a contact pattern 23 according to the invention in the kerf of a semiconductor disk.

In this context, FIG. 6 initially shows in its upper part the layout of a conventional metallic contact pattern 23, which when constructed as test pad exhibits a rectangular shape. In the lower area of FIG. 6, a section of this contact pattern 23 is shown enlarged. In this arrangement, the various metal layers M0, M1, M2 and metal contacts C1, C2, shown in cross section in FIG. 3, can be seen as elongated or square patterns. In the conventional contact pattern 23, the lowest metal layer M0 is constructed directly on the semiconductor surface.

In contrast, the contact pattern 23 according to the invention, shown in FIG. 7, exhibits an integrated fill cell 21. As shown in FIG. 4, the fill patterns 22 are arranged underneath the metal layers M0, M1, M2 of the contact pattern 23. The fill patterns 22 are electrically insulated from the metal layers M0, M1, M2 lying above by means of a dielectric layer 29. As shown in the test pad layout according to the invention of FIG. 7, the entire fill cell 21 is arranged underneath the test pad 23. However, it is possible to provide fill patterns 22 only in a part-area of the test pad 23. Fill areas 21 which only partially extend underneath the contact patterns 23, and also occupy areas outside the contact patterns 23 are similarly conceivable.

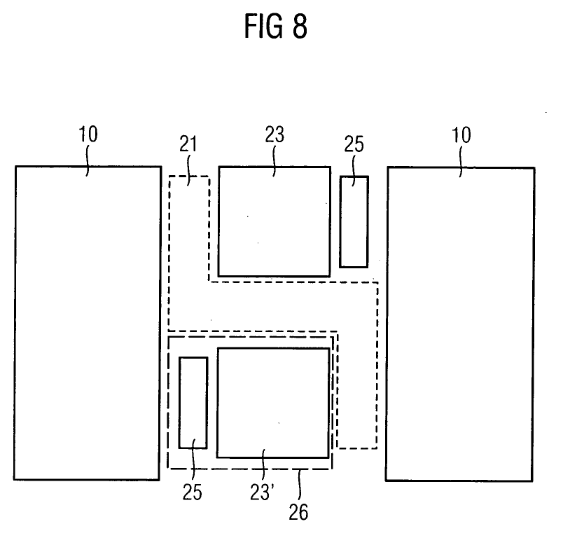

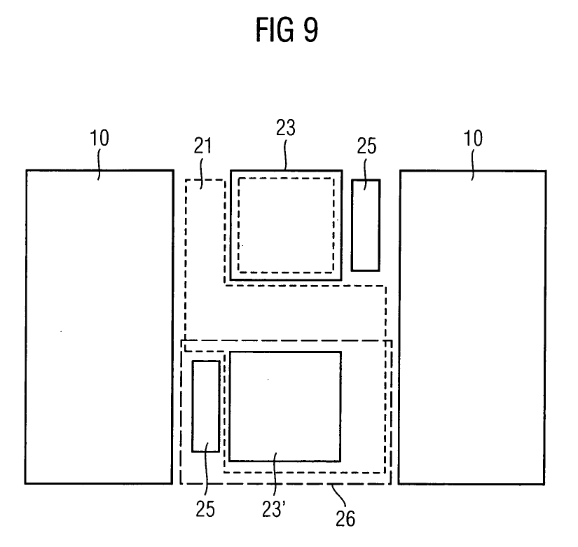

FIGS. 8 and 9 show a comparison between a conventional test pattern area and a test pattern area 26 according to the invention. In this comparison, FIG. 8 shows two contact patterns 23, 23′ in the kerf 20 between two chip areas 10. A test pattern area 26 here comprises the bottom contact pattern 23′ and a test pattern 25′, shown here only by way of example. An automatically generated conventional fill area 21 fills a part of the remaining area in the kerf 20. The greatest proportion of the area in the kerf 20 is occupied by the contact patterns 23, 23′ or by the test area 26, respectively.

In contrast, FIG. 9 shows the fill option according to the invention. In this arrangement, the fill areas are filled with fill patterns which are constructed analogously to the device patterns in the chip areas 10. The upper contact pattern 23 exhibits an integrated fill cell 21′. Furthermore, a further fill area 21 is provided underneath the lower contact pattern 23′ which also occupies areas between the two contact patterns 23, 23′ and between the upper contact pattern 23 and the chip area 10.

As shown in FIG. 9, the construction and arrangement of the fill areas 21 according to the invention leads to a higher packing density of the cell-array-like patterns in the kerf 20 and thus to a more uniform distribution of these patterns along the entire semiconductor disk. As a result, the production conditions can be optimized for lithography.

The invention shown here by way of example is not limited to semiconductor disks for DRAM or flash semiconductor memories, respectively. Instead, the inventive concept can also be applied to any semiconductor memories and to any semiconductor chips.

Features of the invention disclosed in the claims, the description and the drawings can be essential for the invention both individually and in combination.

What is claimed is:

1. A semiconductor disk, comprising:
chip areas arranged next to one another and separated by a kerf, wherein
the chip areas have a multiplicity of similar device patterns,
at least one fill area with fill patterns is arranged in the kerf, and
the fill patterns in the kerf and the device patterns in the chip areas are substantially similarly constructed.

2. The semiconductor disk as claimed in claim 1, wherein the fill patterns in the kerf have the same line widths and distances as the device patterns in the chip areas.

3. The semiconductor disk as claimed in claim 1, wherein the fill patterns in the kerf have the same topography as the device patterns in the chip areas.

4. The semiconductor disk as claimed in claim 1, wherein
at least one plane contact pattern is constructed in the kerf,
the fill area is arranged underneath the contact pattern, and
the contact pattern and the fill patterns in the fill area are electrically insulated from one another by a dielectric layer.

5. The semiconductor disk as claimed in claim 4, further comprising at least one test pattern, which is connected to the contact pattern, arranged in the kerf, wherein the contact pattern is provided for connecting a test device to the test pattern.

6. The semiconductor disk as claimed in claim 1, wherein substantially similar design patterns in the chip areas and in the kerf are substantially homogeneously distributed over the entire semiconductor disk.

7. The semiconductor disk as claimed in claim 1, wherein
at least one test pattern area with at least one test pattern and at least one associated contact pattern is constructed in the kerf, and
the fill area is arranged underneath the test pattern area.

8. The semiconductor disk as claimed in claim 1, wherein each chip area comprises at least one cell array with a multiplicity of memory cells, and the device patterns are constructed as at least one of polysilicon and diffusion patterns of the cell array.

9. The semiconductor disk as claimed in claim 8, wherein the device patterns are constructed as active area strips created in at least one of the semiconductor disk and polysilicon strips created on the semiconductor disk.

10. A test pattern area in a kerf of a semiconductor disk, the semiconductor disk having chip areas arranged next to one another and separated by the kerf, and have a multiplicity of similar device patterns, comprising:
at least one test pattern and a contact pattern which is conductively connected to the test pattern and is used as contact for a test device for testing the test pattern; and
fill patterns, which are constructed analogously to the device patterns, are arranged underneath the contact pattern, wherein
the fill patterns and the contact patterns are separated from one another by a dielectric layer.

11. A method for producing integrated circuits, comprising:
forming chip areas arranged next to one another on a semiconductor disk, which are separated from another via a kerf; and
forming a multiplicity of similar device patterns in the chip areas, wherein
at least one fill area with fill patterns is created in the kerf, and
the device patterns and the fill patterns are similarly created.

12. The method as claimed in claim 11, wherein fill patterns in the kerf are created with the same topography as the device patterns in the chip areas.

13. A semiconductor disk, comprising:
chip areas which are arranged next to one another and which are separated by a kerf, wherein the chip areas in each case exhibit a multiplicity of similar device patterns;
at least one fill area with fill patterns is arranged in the kerf, wherein the fill patterns in the kerf and the device patterns in the chip areas are similarly constructed; and
a test pattern area with at least one plane contact pattern and a test pattern is constructed in the kerf, wherein the fill patterns are arranged underneath the test pattern area and are electrically insulated from one another by a dielectric layer.

14. The semiconductor disk as claimed in claim 13, wherein the fill patterns in the kerf have the same line widths and distances as the device patterns in the chip areas.

15. The semiconductor disk as claimed in claim 13, wherein the fill patterns in the kerf have the same topography as the device patterns in the chip areas.

16. The semiconductor disk as claimed in claim 13, wherein the similarly constructed patterns in the chip areas and in the kerf are homogeneously distributed over the entire semiconductor disk.

17. The semiconductor disk as claimed in claim 13, wherein each chip area comprises at least one cell array with a multiplicity of memory cells, and the device patterns are constructed as at least one of polysilicon and diffusion patterns of the cell array.

18. The semiconductor disk as claimed in claim 17, wherein the device patterns are constructed as active-area strips created in at least one of the semiconductor disk and polysilicon strips created on the semiconductor disk.

19. A method for producing integrated circuits, comprising:
creating chip areas arranged next to one another on a semiconductor disk, which are separated from one another by a kerf;
creating a multiplicity of similar device patterns in the chip areas;
creating at least one fill area with fill patterns in the kerf, wherein the fill patterns in the kerf and the device patterns in the chip areas are similarly constructed,
constructing a test pattern area with at least one plane contact pattern and one test pattern in the kerf, wherein the fill patterns are arranged underneath the test pattern area and are electrically insulated from one another by a dielectric layer.

20. The method as claimed in claim 19, wherein fill patterns in the kerf are created with the same topography as the device patterns in the chip areas.

21. The method as claimed in claim 20, wherein at least one contact pattern is created at least partially on the fill area in the kerf, abd a dielectric layer is created between the fill patterns in the fill area and the contact pattern.
